(19) United States
(12) Patent Application Publication
(10) Pub. No.: US 2009/0250102 A1
(43) Pub. Date: Oct. 8, 2009

(54) PHOTOELECTRIC CONVERSION DEVICE USING SEMICONDUCTOR NANOMATERIALS AND METHOD OF MANUFACTURING THE SAME

(75) Inventors: Joon-Dong Kim, Seo-gu (KR); Chang-Soo Han, Yuseong-gu (KR); Eung-Sug Lee, Masan-si (KR); Byung-Ik Choi, Seo-gu (KR); Kyung-Hyun Whang, Gangnam-gu (KR)

Correspondence Address: OBLON, SPIVAK, MCCLELLAND MAIER & NEUSTADT, P.C., 1940 DUKE STREET, ALEXANDRIA, VA, 22314, US

(73) Assignee: Korea Institute of Machinery & Materials, Yuseong-gu (KR)

(21) Appl. No.: 12/209,493

(22) Filed: Sep. 12, 2008

(30) Foreign Application Priority Data
Apr. 2, 2008 (KR) 10-2008-0030951

(51) Int. Cl. H01L 31/00; H01L 21/00

(52) U.S. Cl. 136/255; 438/92; 257/E21.359

(57) ABSTRACT

A photoelectric conversion device using a semiconductor nanomaterial to which a rectifying action caused by a Schottky junction between semiconductor nanomaterials and metal is applied and a method of manufacturing the same are provided. The photoelectric conversion device includes a substrate, an insulating layer formed on the substrate, a nanomaterial layer made of a plurality of semiconductor nanomaterials vertically arranged between the insulating layer or horizontally arranged on the substrate, and a metal layer provided on the semiconductor nanomaterial layer to form a Schottky junction with the semiconductor nanomaterials. The electrical energy is generated by rectification generated between the semiconductor nanomaterials and the metal layer that form the Schottky junction with each other.

### BACKGROUND OF THE INVENTION

1. Field of the Invention

The present invention relates generally to a photoelectric conversion device and a method of manufacturing the same and, more particularly, to a photoelectric conversion device using semiconductor nanomaterials to which a rectifying action caused by a Schottky junction between the semiconductor nanomaterials and metal is applied and a method of manufacturing the same.

2. Description of the Related Art

Since a solar cell as a photoelectric conversion device converting light having photon energy such as sunlight into electrical energy is limitless and environmentally friendly unlike other energy sources, the importance of the solar cell increases with the lapse of time.

In particular, when the solar cell is mounted in various portable information apparatuses such as a portable computer, a mobile phone, and a personal portable terminal, the solar cell is expected to be charged only by the sunlight.

A single-crystalline or poly-crystalline silicon wafer shaped solar cell that is a first generation solar cell is widely used as the existing solar cell. However, the manufacturing cost of the silicon wafer shaped solar cell is high because of using a large scaled and expensive apparatus and high price of raw material and it is difficult to improve efficiency of converting solar energy into electrical energy.

Then, a second generation thin film solar cell is replacing such a silicon wafer solar cell and is utilized in the form of a thin film solar cell requiring a small amount of silicon.

Recently, interest in a solar cell using organic material as a third generation solar cell manufactured at a low price has rapidly increased. In particular, a dye-sensitized solar cell having low manufacturing cost is spotlighted.

FIG. 1 schematically illustrates a p-n junction semiconductor solar cell.

Referring to FIG. 1, the solar cell includes the p-n junction formed by combining a p-type semiconductor 110 and an n-type semiconductor 120, an anti-reflection (AR) layer 130 reducing the reflection loss of light, a front contact electrode 140, and a rear contact electrode 150.

Due to the characteristics of a semiconductor, when the semiconductor absorbs light (photon) by photoelectric effect, free electrons and holes are generated. In a common semiconductor, the free electrons and the holes are recombined with each other to convert absorbed photon energy into phonon energy such as heat. However, in the solar cell, since the positions of the free electrons and holes around the p-n junction are exchanged due to an electromagnetic field around the p-n junction so that electric potential is generated, when a device is connected to the outside of the solar cell, electric current flows as a result.

That is, as illustrated in FIG. 2, when light hits the solar cell, light is absorbed into the solar cell. The holes and the electrons are generated by the energy of the absorbed light to freely move in the solar cell. However, the electrons gather into the n-type semiconductor and the holes gather into the p-type semiconductor so that electric potential is generated.

When load is connected between the electrode 140 connected to the n-type semiconductor and the electrode 150 connected to the p-type semiconductor, current flows, which is the basic principle of the generation of electric power caused by the p-n junction of the solar cell.

In the photoelectric conversion device, the reflectance of incident light from the outside is high and the re-absorption ratio of the incident light from the outside is low so that electric power generation efficiency of the sunlight is low.

Since an expensive large area substrate is to be used, the manufacturing cost is high. Since a p-type substrate is doped with an opposite type semiconductor, that is, the n-type semiconductor and an n-type substrate is doped with an opposite type semiconductor, that is, the p-type semiconductor, the manufacturing processes are complicated.

In a related art, since a texturing process of forming pyramid-shaped indentations on the surface of the substrate in order to reduce the reflectance of the incident light is performed, the processes increase.

### SUMMARY OF THE INVENTION

The present invention has been made in view of the above problems, and the present invention provides a photoelectric conversion device using semiconductor nanomaterials in which the semiconductor nanomaterials are arranged on a substrate and a metal layer forming a Schottky junction with the semiconductor nanomaterials is formed to generate the flow of electrons and holes when sunlight enters due to a difference in the work function of the metal forming the Schottky junction with the semiconductor nanomaterials and to induce electric current and a method of manufacturing the same.

In accordance with an aspect of the present invention, there is provided a photoelectric conversion device for converting optical energy having photon energy into electrical energy, comprising: a substrate; an insulating layer formed on the substrate; a nanomaterial layer made of a plurality of semiconductor nanomaterials vertically arranged in the insulating layer; and a metal layer provided on the semiconductor nanomaterial layer to form a Schottky junction with the semiconductor nanomaterials, wherein the electrical energy is generated by rectification generated between the semiconductor nanomaterials and the metal layer that form the Schottky junction with each other.

In accordance with another aspect of the present invention, there is provided a photoelectric conversion device for converting optical energy having photon energy into electric energy comprising: a substrate; a nanomaterial layer made of a plurality of semiconductor nanomaterials horizontally arranged on the substrate; and a metal layer provided on the semiconductor nanomaterial layer to form a Schottky junction with the semiconductor nanomaterials, wherein the electrical energy is generated by rectification generated between the semiconductor nanomaterials and the metal layer that form the Schottky junction with each other.

In accordance with still another aspect of the present invention, there is provided a method of manufacturing a photoelectric conversion device using semiconductor nanomaterials for converting optical energy having photon energy into electric energy by a rectifying action generated by a Schottky junction between the semiconductor nanomaterials and a metal layer, the method comprising: forming a semiconductor nanomaterial layer by vertically arranging a plurality of semiconductor nanomaterials on a substrate; forming an insulating layer between the semiconductor nanomaterials to separate the semiconductor nanomaterials from each other; and forming the metal layer on the insulating layer so that the metal layer forms a Schottky junction with the semiconductor nanomaterials.

In accordance with an aspect of the present invention, there is provided a method of manufacturing a photoelectric conversion device using semiconductor nanomaterials for converting optical energy having photon energy into electrical energy by a rectifying action generated by a Schottky junction between the semiconductor nanomaterials and a metal layer, the method comprising: forming a semiconductor nanomaterial layer by horizontally arranging a plurality of semiconductor nanomaterials on the substrate; and forming the metal layer on the semiconductor nanomaterial layer so that the metal layer forms a Schottky junction with the semiconductor nanomaterials.

In a feature of the present invention, since an additional p-n junction is not used but the flows of the electrons and the holes are induced by sunlight due to a difference between the work functions of the semiconductor nanomaterials and the metal layer forming a Schottky junction to generate electric current so that additional doping and texturing processes are not required, processes can be simplified.

In addition, the conductive substrate is used as the rear contact electrode or the metal layer is used as the front contact electrode so that elements and processes can be simplified.

According to the present invention, light is repeatedly reflected and re-absorbed between the vertically arranged semiconductor nanomaterials so that electrical energy generation efficiency can be improved due to reduction in the reflectance of light and increase in the re-absorption ratio of light.

### BRIEF DESCRIPTION OF THE DRAWINGS

The objects, features and advantages of the present invention will be more apparent from the following detailed description in conjunction with the accompanying drawings, in which:

FIG. 1 schematically illustrates a common p-n junction semiconductor solar cell that is an example of a photoelectric conversion device;

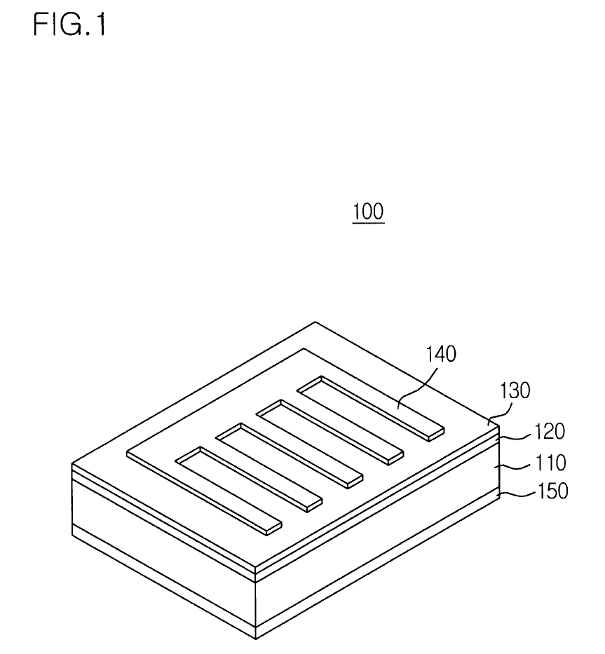

FIG. 2 schematically illustrates the principle of the generation of electric power using the p-n junction of the photoelectric conversion device;

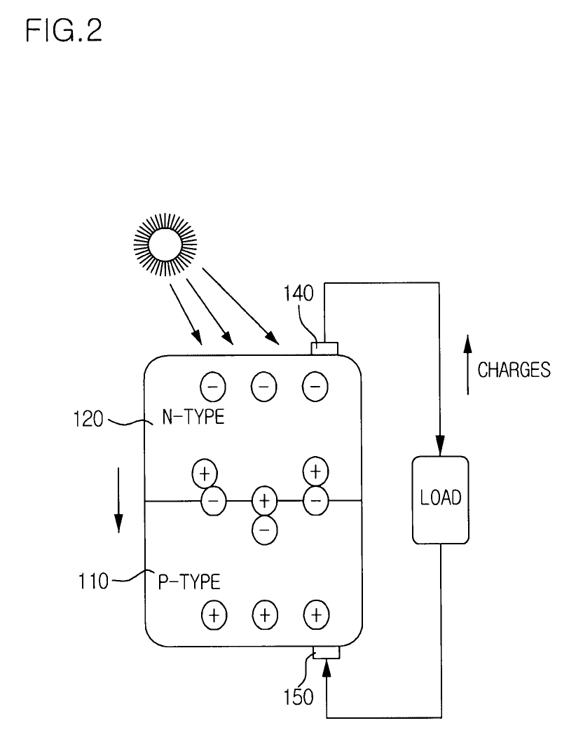

FIG. 3 is a sectional view of a photoelectric conversion device using semiconductor nanomaterials according to a first embodiment of the present invention;

FIGS. 4 and 5 illustrate the operation of the solar cell according to the embodiment of the present invention;

FIG. 6 is a sectional view of a photoelectric conversion device using semiconductor nanomaterials according to a second embodiment of the present invention;

FIG. 7 is a sectional view of a photoelectric conversion device using semiconductor nanomaterials according to a third embodiment of the present invention; and

FIG. 8 is a sectional view of a photoelectric conversion device using semiconductor nanomaterials according to a fourth embodiment of the present invention.

### DETAILED DESCRIPTION OF EXEMPLARY EMBODIMENTS

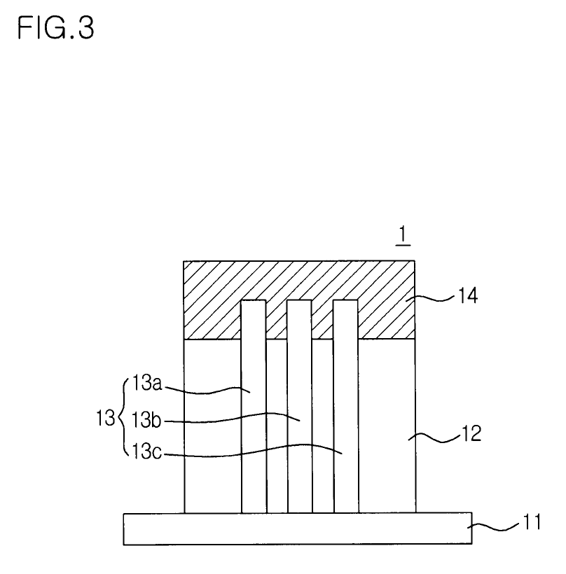

FIG. 3 is a sectional view of a photoelectric conversion device using semiconductor nanomaterials according to a first embodiment of the present invention. The present invention relates to a photoelectric conversion device for converting optical energy having photon energy into electrical energy.

Referring to FIG. 3, a photoelectric conversion device 1 according to the first embodiment of the present invention includes a substrate 11, an insulating layer 12, a semiconductor nanomaterial layer 13, and a metal layer 14.

Here, a conductive substrate may be used as the substrate 11 and, when the conductive substrate is used as the substrate 11, the substrate 11 serves as a rear electrode.

The insulating layer 12 serves as a semiconductor nanomaterial supporting layer and may be formed of a transparent material having a large dielectric constant such as SiO₂ and SiN to serve as a reflection preventing layer.

The semiconductor nanomaterial layer 13 is vertically arranged in the insulating layer 12 and made of a plurality of semiconductor nanomaterials 13a, 13b, and 13c having the characteristics of semiconductor. The metal layer 14 is provided at the upper side of the semiconductor nanomaterial layer 13 forming a Schottky junction with the semiconductor nanomaterials 13a, 13b, and 13c.

The electrical energy is generated by rectification generated between the semiconductor nanomaterials 13a, 13b, and 13c and the metal layer 14 forming the Schottky junction with each other in accordance with the characteristics of the present invention.

That is, when light having the photon energy enters between the semiconductor nanomaterials 13a, 13b, and 13c and the metal layer 14 forming the Schottky junction, the electrons and the holes move in the opposite directions so that rectified current is generated.

Therefore, according to the present invention, in order to obtain the electrical energy caused by the flows of the electrons and the holes between the semiconductor nanomaterials 13a, 13b, and 13c and the metal layer 14, when n-type semiconductor nanomaterial is used, the work function Φs of the n-type semiconductor nanomaterials must be larger than the work function Φm of the metal layer 14 and, when p-type semiconductor nanomaterials are used, the work function Φs of the p-type semiconductor nanomaterials must be smaller than the work function Φm of the metal layer 14.

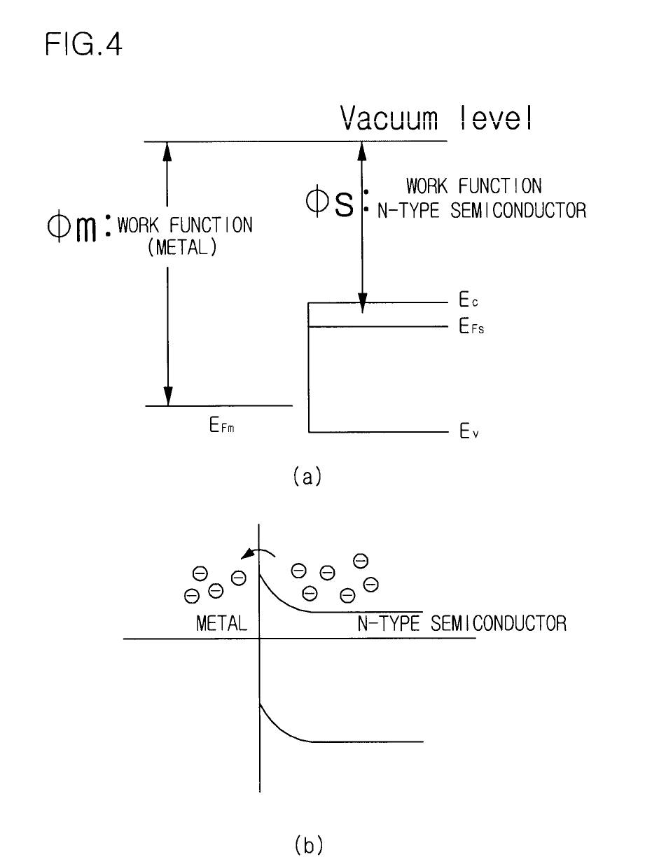

In other words, as illustrated in FIG. 4A, when the work function Φs of the n-type semiconductor nanomaterials is larger than the work function Φm of the metal layer, the electrons of the n-type semiconductor nanomaterials, as illustrated in FIG. 4B, pass over a potential barrier layer to move in the direction of the metal layer 14, and the holes move in the opposite direction to generate the electric current.

As illustrated in FIG. 5A, when the work function Φs of the p-type semiconductor nanomaterials is smaller than the work function Φm of the metal layer 14, the electrons in the metal layer 14, as illustrated in FIG. 5B, pass over the potential barrier layer to move in the direction of the semiconductor nanomaterials 13a, 13b, and 13c, and the holes move in the opposite direction to generate the electric current.

On the other hand, the semiconductor nanomaterials 13a, 13b, and 13c in this embodiment of the present invention may be formed of at least one selected from group 4 intrinsic semiconductors, group 4-4 compound semiconductors, group 3-5 compound semiconductors, group 2-6 compound semiconductors, and group 4-6 compound semiconductors and the characteristics thereof may be changed by performing additional doping or including an additional junction.

Although in the existing photoelectric conversion device using the p-n junction a front junction metal is further provided, the metal layer 14, in the first embodiment of the present invention, maybe used as the front electrode.

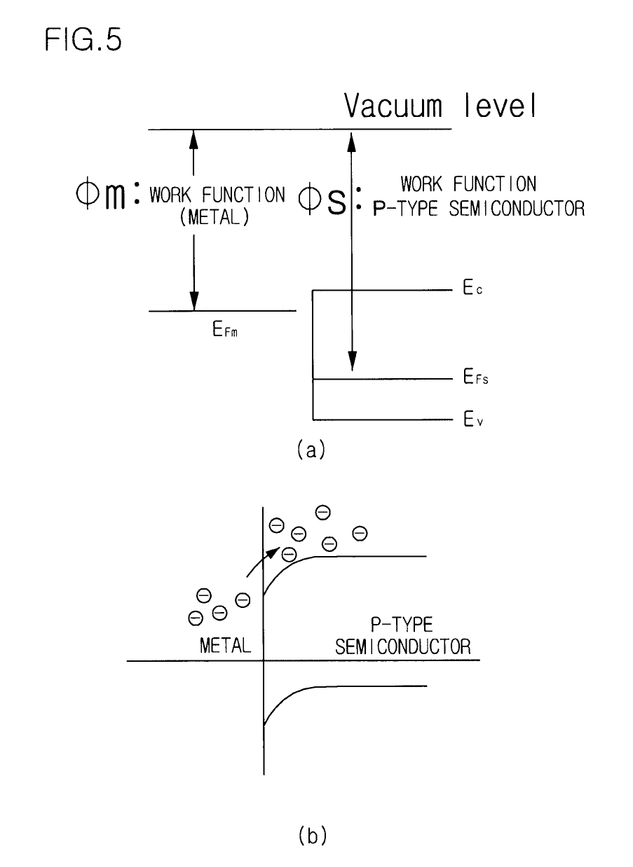

FIG. 6 is a sectional view of a photoelectric conversion device using semiconductor nanomaterials according to a second embodiment of the present invention. Detailed description of the same elements as the above-described elements according to the first embodiment of the present invention will be omitted.

Referring to FIG. 6, the photoelectric conversion device using the semiconductor nanomaterials according to the second embodiment of the present invention includes the substrate 11, the insulating layer 12, the semiconductor nanomaterial layer 13, the metal layer 14, and a front electrode 15. Generation of electric current is the same as the operations according to the first embodiment of the present invention.

Here, the front electrode 15 forms an ohmic junction with the metal layer 14.

According to the first and second embodiments of the present invention, the conductive substrate is used as the rear electrode, the current is generated from the semiconductor nanomaterials and the metal layer forming a Schottky junction, and the metal layer is used as the rear layer to simplify the structure of the photoelectric conversion device.

In the related art, in order to reduce the reflectance of the incident light, a texturing process of forming pyramid-shaped indentations on the surface of the substrate is performed. However, in the present invention, since the plurality of vertically arranged semiconductor nanomaterials functions as being textured, the reflectance may be reduced without the texturing process.

That is, some of the incident light is absorbed into the surface of one semiconductor nanomaterial and the rest of the incident light is reflected. Since semiconductor nanomaterials are arranged adjacent to the reflection path of the reflected light, light is re-absorbed from the adjacent semiconductor nanomaterials so that the reflectance is significantly reduced.

As described above, according to the first and second embodiments of the present invention, since the structure of the photoelectric conversion device is simplified and the reflectance is significantly reduced electrical energy generation efficiency can be improved.

The photoelectric conversion devices using the semiconductor nanomaterials according to the first and second embodiments of the present invention are manufactured by the following processes.

First, the plurality of semiconductor nanomaterials 13a, 13b, and 13c are vertically arranged on the substrate 11 to form the semiconductor nanomaterial layer 13.

In this case, the semiconductor nanomaterials 13a, 13b, and 13c may be grown and arranged by a chemical vapor deposition (CVD), a physical vapor deposition (PVD), or an electrochemical method or previously composed semiconductor nanomaterials may be arranged on the substrate The semiconductor nanomaterials grown by the CVD, the PVD, or the electrochemical method may be arranged by a spin coating method or a printing method.

The semiconductor nanomaterial layer 13 may be formed by arranging the semiconductor nanomaterials grown by a nanomaterial growth method by the spin coating method or the printing method and patterning the semiconductor nanomaterials by an imprint or an etching process, or may be formed by etching a substrate having the characteristics of semiconductor.

Then, the insulating layer 12 is formed between the semiconductor nanomaterials 13a, 13b, and 13c so that the semiconductor nanomaterials are separated from each other.

In this case, the insulating layer 12 is coated so that the semiconductor nanomaterials 13a, 13b, and 13c are partially exposed at the upper portions by a preset length. Alternately, the semiconductor nanomaterials 13a, 13b, and 13c are completely buried such that the upper portions of the semiconductor nanomaterials 13a, 13b, and 13c are partially exposed by an etching process.

Then, the metal layer 14 is formed on the insulating layer 12 to form a Schottky junction with the semiconductor nanomaterials 13a, 13b, and 13c.

The above-described processes of the second embodiment of are the same as those of the first embodiment. However, in the second embodiment, a process of forming the front electrode 15 on the metal layer 14 is further performed.

In the existing photoelectric conversion device using the p-n junction, an n-type doping process is performed when a p-type substrate is used and a p-type doping process is performed when an n-type substrate is used. However, in the present invention, since the doping process is not performed, processes can be reduced.

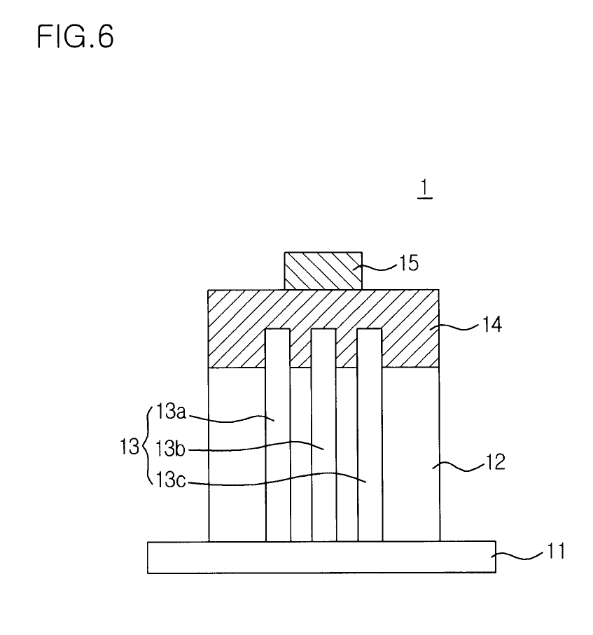

FIG. 7 is a sectional view of a photoelectric conversion device using semiconductor nanomaterials according to a third embodiment of the present invention. Description of the same elements and operations as those in the first and second embodiments of the present invention will be omitted.

Referring to FIG. 7, the photoelectric conversion device 2 according to the third embodiment of the present invention includes a substrate 21, a semiconductor nanomaterial layer 22, an insulating layer 23, a metal layer 24, and a rear electrode 25.

Here, the substrate 21 is a non-conductive substrate and the semiconductor nanomaterial layer 22 is made of a plurality of semiconductor nanomaterials 22a arranged on the substrate 21 in the form of a tree.

The metal layer 24 is formed on the semiconductor nanomaterial layer 22 to form a Schottky junction with the semiconductor nanomaterials 22a so that the electrical energy is generated by rectification generated between the semiconductor nanomaterials and the metal layer 24.

The metal layer 24 serves as the front electrode or, although not shown in the drawing, may further include a front electrode (not shown) provided on the metal layer 24 and be formed of a metal material forming an ohmic junction with the metal layer 24.

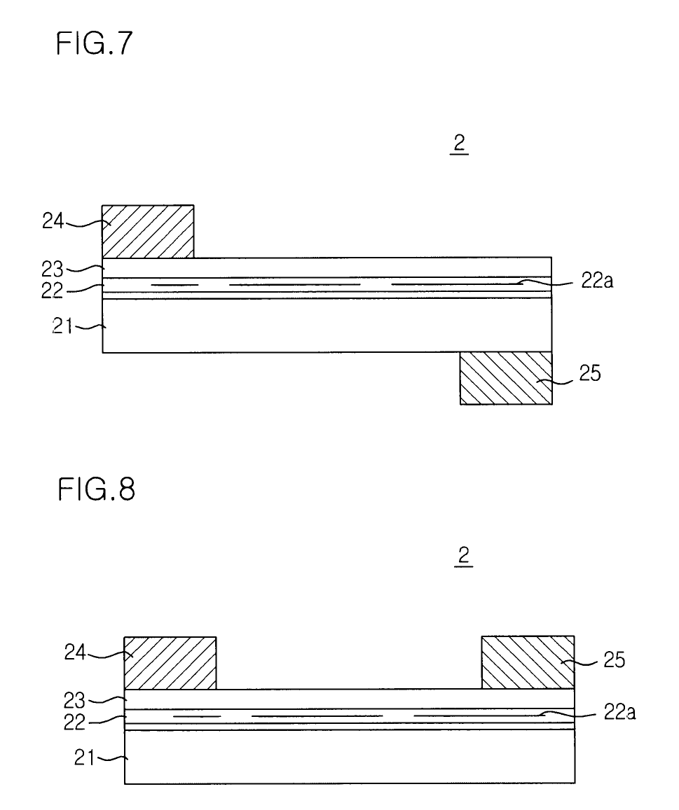

FIG. 8 is a sectional view of a photoelectric conversion device using semiconductor nanomaterials according to a fourth embodiment of the present invention. Description of the same elements and operations as those in the first and third embodiments of the present invention will be omitted.

Referring to FIG. 8, the photoelectric conversion device according to the fourth embodiment of the present invention includes the substrate 21, the semiconductor nanomaterial layer 22, the insulating layer 23, the metal layer 24, and the rear electrode 25.

In the above-described third embodiment, the rear electrode 25 is provided under the substrate 21. However, in the fourth embodiment, the rear electrode 25 is provided on one side of the semiconductor nanomaterial layer 21.

The rear electrode 25 is made of a metal forming an ohmic junction with the semiconductor nanomaterials 22a. In the drawing, the metal layer 24 is used as the front electrode. However, according to another modification, a front electrode (not shown) made of a metal forming the ohmic junction with the metal layer 24 may be further provided on the metal layer 24.

The photoelectric conversion devices using the semiconductor nanomaterials according to the third and fourth embodiments of the present invention are manufactured by the following processes.

First, the plurality of semiconductor nanomaterials 22a are horizontally arranged on the substrate 21 to form the semiconductor nanomaterial layer 22.

In this case, the semiconductor nanomaterial layer 22 may be formed by growing and arranging the semiconductor nanomaterials by the CVD, the PVD, or the electrochemical method or by arranging previously composed semiconductor nanomaterials on the substrate 21.

Alternately, the semiconductor nanomaterial layer 22 may be formed by spin-coating or printing the semiconductor nanomaterials grown by the CVD, the PVD, or the electrochemical method.

Alternately, the semiconductor nanomaterial layer 22 may be formed by imprinting or etching the semiconductor nanomaterials grown by a nanomaterial growth method to be arranged by the spin coating method or the printing method, or may be formed by etching a substrate having the characteristics of semiconductor.

The insulating layer 23 is formed on the semiconductor nanomaterial layer 22 and the metal layer 24 is formed to form a Schottky junction with the semiconductor nanomaterials 22a.

In this case, the insulating layer 23 is depicted in the drawing. However, the insulating layer 23 may be omitted in another modification. When the insulating layer 23 is formed, the insulating layer 23 is preferably formed thin so that the semiconductor nanomaterials 22a form a Schottky junction with the metal layer 24.

In the third embodiment, the rear electrode 25 is formed to the lower side of the substrate 21. In the fourth embodiment, a rear electrode formed of a metal forming an ohmic junction with the semiconductor nanomaterials is further provided on one side of the semiconductor nanomaterial layer 22.

Although not shown in the drawing, a front electrode (not shown) made of a metal forming an ohmic junction with the metal layer may be further formed on the metal layer Although exemplary embodiments of the present invention have been described in detail hereinabove, it should be understood that many variations and modifications of the basic inventive concept herein described, which may appear to those skilled in the art, will still fall within the spirit and scope of the exemplary embodiments of the present invention as defined in the appended claims.

What is claimed is:

1. A photoelectric conversion device for converting optical energy having photon energy into electrical energy, comprising:
a substrate;
an insulating layer formed on the substrate;
a nanomaterial layer made of a plurality of semiconductor nanomaterials vertically arranged in the insulating layer; and
a metal layer provided on the semiconductor nanomaterial layer to form a Schottky junction with the semiconductor nanomaterials,
wherein the electrical energy is generated by rectification generated between the semiconductor nanomaterials and the metal layer that form the Schottky junction with each other.

2. A photoelectric conversion device for converting optical energy having photon energy into electrical energy, comprising:
a substrate;
a nanomaterial layer made of a plurality of semiconductor nanomaterials horizontally arranged on the substrate; and
a metal layer provided on the semiconductor nanomaterial layer to form a Schottky junction with the semiconductor nanomaterials,
wherein the electrical energy is generated by rectification generated between the semiconductor nanomaterials and the metal layer that form the Schottky junction with each other.

3. The photoelectric conversion device of claim 2, further comprising an insulating layer of a thickness formed between the semiconductor nanomaterial layer and the metal layer such that the semiconductor nanomaterials and the metal layer form a Schottky junction with each other.

4. The photoelectric conversion device of claim 1, wherein the substrate is made of a conductive substrate to be used as a rear electrode.

5. The photoelectric conversion device of claim 3, further comprising a rear electrode formed to the lower side of the substrate.

6. The photoelectric conversion device of claim 3, further comprising a rear electrode made of a metal forming an ohmic junction with the semiconductor nanomaterials on one side of the semiconductor nanomaterial layer.

7. The photoelectric conversion device of any one of claims 1 to 6, wherein the metal layer is used as a front electrode.

8. The photoelectric conversion device of any one of claims 1 to 6, further comprising a front electrode made of a metal material forming an ohmic junction with the metal layer on the metal layer.

9. The photoelectric conversion device of any one of claims 1 to 6, wherein characteristics of the semiconductor nanomaterials change by performing doping or addition of a junction.

10. The photoelectric conversion device of claim 1, wherein the insulating layer is a semiconductor nanomaterial supporting layer.

11. The photoelectric conversion device of claim 1 or any one of claims 3 to 6, wherein the insulating layer is a transparent reflection preventing layer.

12. The photoelectric conversion device of any one of claims 1 to 6, wherein the semiconductor nanomaterials are selected from a group consisting of group 4 intrinsic semiconductors, group 4-4 compound semiconductors, group 3-5 compound semiconductors, group 2-6 compound semiconductors, and group 4-6 compound semiconductors.

13. The photoelectric conversion device of any one of claims 1 to 6, wherein the semiconductor nanomaterials are n-type semiconductor so that a work function (Φs) of the semiconductor nanomaterials is larger than a work function (Φm) of the metal layer.

14. The photoelectric conversion device of any one of claims 1 to 6, wherein the semiconductor nanomaterials are a p-type semiconductor so that the work function (Φs) of the semiconductor nanomaterials is smaller than the work function (Φm) of the metal layer.

15. A method of manufacturing a photoelectric conversion device using semiconductor nanomaterials for converting optical energy having photon energy into electrical energy by rectification generated by a Schottky junction between the semiconductor nanomaterials and a metal layer, the method comprising:
forming a semiconductor nanomaterial layer by vertically arranging a plurality of semiconductor nanomaterials on a substrate;
forming an insulating layer between the semiconductor nanomaterials to separate the semiconductor nanomaterials from each other; and
forming the metal layer on the insulating layer so that the metal layer forms a Schottky junction with the semiconductor nanomaterials.

16. The method of claim 15, wherein, in the formation of the insulating layer, upper portions of the plurality of vertically arranged semiconductor nanomaterials are coated to be exposed by a preset length.

17. The method of claim 15, wherein, in the formation of the insulating layer, the vertically arranged semiconductor nanomaterials are coated with the insulating layer by a length of the upper portions of the semiconductor nanomaterials, and are partially exposed at the upper portions by a predetermined length by etching.

18. The method of claim 15, wherein the substrate is made of a conductive substrate to be used as a rear electrode.

19. A method of manufacturing a photoelectric conversion device using semiconductor nanomaterials for converting optical energy having photon energy into electrical energy by rectification generated by a Schottky junction between the semiconductor nanomaterials and a metal layer, the method comprising:
forming a semiconductor nanomaterial layer by horizontally arranging a plurality of semiconductor nanomaterials on the substrate; and
forming the metal layer on the semiconductor nanomaterial layer so that the metal layer forms a Schottky junction with the semiconductor nanomaterials.

20. The method of claim 19, wherein an insulating layer of a thickness is further formed between the semiconductor nanomaterial layer and the metal layer to allow the semiconductor nanomaterials and the metal layer to form a Schottky junction with each other provided.

21. The method of claim 20, wherein a rear electrode is further formed at the lower side of the substrate.

22. The method of claim 20 wherein a rear electrode made of a metal forming an ohmic junction with the semiconductor nanomaterials is further formed on one side of the semiconductor nanomaterial layer.

23. The method of any one of claims 15 to 22, wherein a front electrode made of a metal forming an ohmic junction with the metal layer is further formed on the metal layer.

24. The method of any one of claims 15 to 22, wherein characteristics of the semiconductor nanomaterial layer are changed by performing doping or addition of a junction to the semiconductor nanomaterial layers.

25. The method of any one of claims 15 to 18, wherein the insulating layer is a nanofiber supporting layer.

26. The method of any one of claims 15 to 18 or 20 to 22, wherein the insulating layer is made of a transparent reflection preventing layer.

27. The method of any one of claims 15 to 22, wherein the semiconductor nanomaterials are made of at least one selected from a group consisting of group 4 intrinsic semiconductors, group 4-4 compound semiconductors, group 3-5 compound semiconductors, group 2-6 compound semiconductors, and group 4-6 compound semiconductors.

28. The method of any one of claims 15 to 22, wherein the semiconductor nanomaterials are made of an n-type semiconductor such that a work function (Φs) of the semiconductor nanomaterials is larger than a work function (Φm) of the metal layer.

29. The method of any one of claims 15 to 22, wherein the semiconductor nanomaterials are made of a p-type semiconductor such that the work function (Φs) of the semiconductor nanomaterials is smaller than the work function (Φm) of the metal layer.

30. The method of anyone of claims 15 to 22, wherein, in the formation of the semiconductor nanomaterial layer, the semiconductor nanomaterials are grown by a chemical vapor deposition (CVD), a physical vapor deposition (PVD), or an electrochemical method.

31. The method of any one of claims 15 to 22, wherein, in the formation of the semiconductor nanomaterial layer, the semiconductor nanomaterials grown by a nanomaterial growth method are arranged by spin-coating or printing.

32. The method of anyone of claims 15 to 22, wherein, in the formation of the semiconductor nanomaterial layer, after the semiconductor nanomaterials grown by the nanomaterial growth method are arranged by spin-coating or printing, the semiconductor nanomaterials are patterned by imprinting or etching.

33. The method of anyone of claims 15 to 22, wherein, in the formation of the semiconductor nanomaterial layer, a substrate having characteristics of semiconductor is etched to form a nanostructure.
